(19) United States
(12) Patent Application Publication
(10) Pub. No.: US 2009/0046417 A1
(43) Pub. Date: Feb. 19, 2009

(54) Integrated Meter/Timer

(75) Inventors: Kenneth W. Pabst, Northbrook, IL (US); John DeCosmo, Glenview, IL (US); Howard L. Frank, Skokie, IL (US); Brian M. Gleason, Des Plaines, IL (US)

Correspondence Address: NIXON PEABODY, LLP, 161 N. CLARK ST., 48TH FLOOR, CHICAGO, IL, 60601-3213, US

(73) Assignee: Ulta-Lit Tree Co., Glenview, IL (US)

(21) Appl. No.: 12/189,927

(22) Filed: Aug. 12, 2008

Related U.S. Application Data
(60) Provisional application No. 60/965,056, filed on Aug. 16, 2007.

(51) Int. Cl. H05K 7/10

(52) U.S. Cl. 361/681

(57) ABSTRACT

An integrated meter/timer comprises a plug adapted to be plugged into an electrical outlet connected to a power distribution circuit, a socket for receiving a plug from an electrical appliance, an electrical connection between the plug and the socket that includes a controllable switch for opening and closing the electrical connection to control the supplying of electrical power to the appliance, a current sensor coupled to the electrical connection for producing a signal representing the magnitude of electrical current flowing in the electrical connection, a microprocessor receiving the signal and producing a display signal representing a numerical value corresponding to the current magnitude, and a display coupled to the microprocessor for receiving the display signal for displaying the numerical value.

### CROSS-REFERENCE TO RELATED APPLICATIONS

This application claims priority to U.S. Provisional Application Ser. No. 60/965,056 filed Aug. 16, 2007.

### FIELD OF THE INVENTION

The present invention relates generally to the fields of electronic timers for automatically turning electrical appliances such as lights on and off at preset times, and electronic ammeters for detecting and displaying the level of electrical current flowing in a power circuit.

### BACKGROUND OF THE INVENTION

The use of timers to automatically turn lights or other appliances on and off has become commonplace. Certain of these timers are especially designed for outdoor use and include ambient light sensors to turn outdoor lights on and off in response to the ambient light level (e.g., turn lights on at dusk and off at dawn). The use of timers, however, can lead to issues such as the cost of power consumed during operations controlled by the timers, and the cause of power interruptions that occur in a power distribution circuit that includes one or more timers. In the event of a power interruption in a power distribution circuit that includes one or more timers, the cause of the interruption is not always clear. For example, it might not be clear whether one or more devices controlled by timers contributed to the interruption.

### SUMMARY OF THE INVENTION

In one embodiment, an integrated meter/timer comprises a plug adapted to be plugged into an electrical outlet connected to a power distribution circuit, a socket for receiving a plug from an electrical appliance, an electrical connection between the plug and the socket that includes a controllable switch for opening and closing the electrical connection to control the supplying of electrical power to the appliance, a current sensor coupled to the electrical connection for producing a signal representing the magnitude of electrical current flowing in the electrical connection, a microprocessor receiving the signal and producing a display signal representing a numerical value corresponding to the current magnitude, and a display coupled to the microprocessor for receiving the display signal for displaying the numerical value. The microprocessor also produces a signal controlling the opening and closing the switch to turn the appliance on and off.

One particular implementation includes a memory, and the microprocessor is programmed to store the peak value of the current magnitude in the memory, and to retrieve the stored peak value for display.

Another implementation includes an ambient light sensor for generating a switch control signal, and the microprocessor is programmed to generate a switch actuating signal in response to the switch control signal. The switch may include a relay responsive to the control signal for opening and closing the switch.

### BRIEF DESCRIPTION OF THE DRAWINGS

The invention may best be understood by reference to the following description taken in conjunction with the accompanying drawings, in which:

FIG. 1 is a front perspective of one embodiment of a meter/timer utilizing the invention.

FIG. 2 is a side elevation of the meter/timer of FIG. 1.

FIG. 3 is a diagram of the electrical system included in the meter/timer of FIGS. 1 and 2.

### DETAILED DESCRIPTION OF THE ILLUSTRATED EMBODIMENT

Although the invention will be described in connection with certain preferred embodiments, it will be understood that the invention is not limited to those particular embodiments. On the contrary, the invention is intended to cover all alternatives, modifications, and equivalent arrangements as may be included within the spirit and scope of the invention as defined by the appended claims.

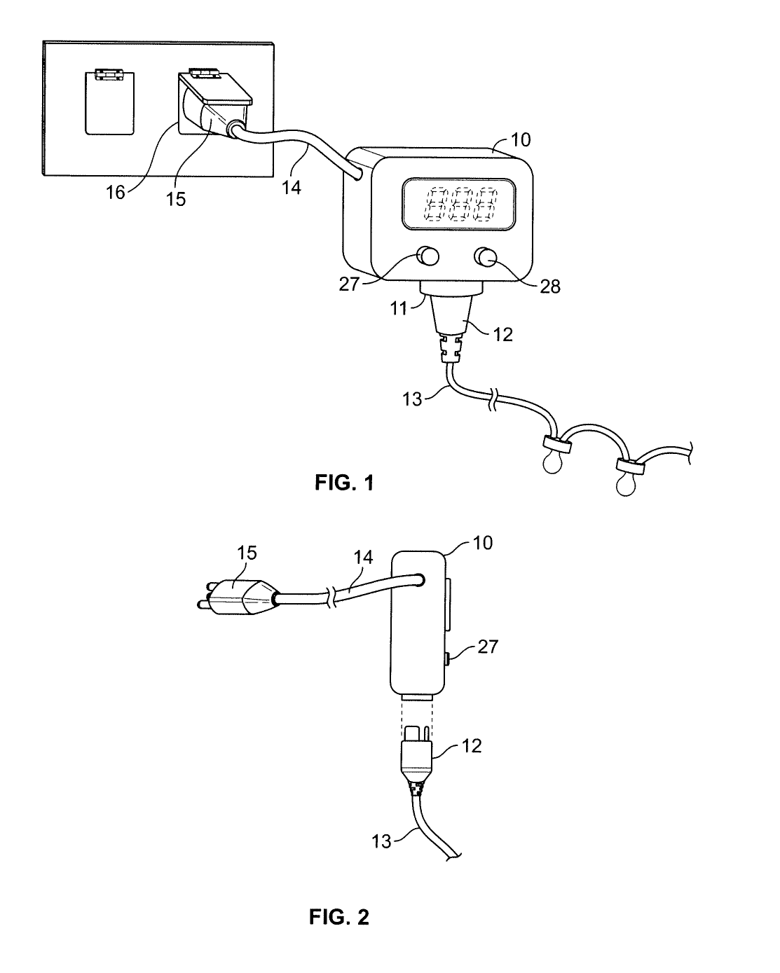

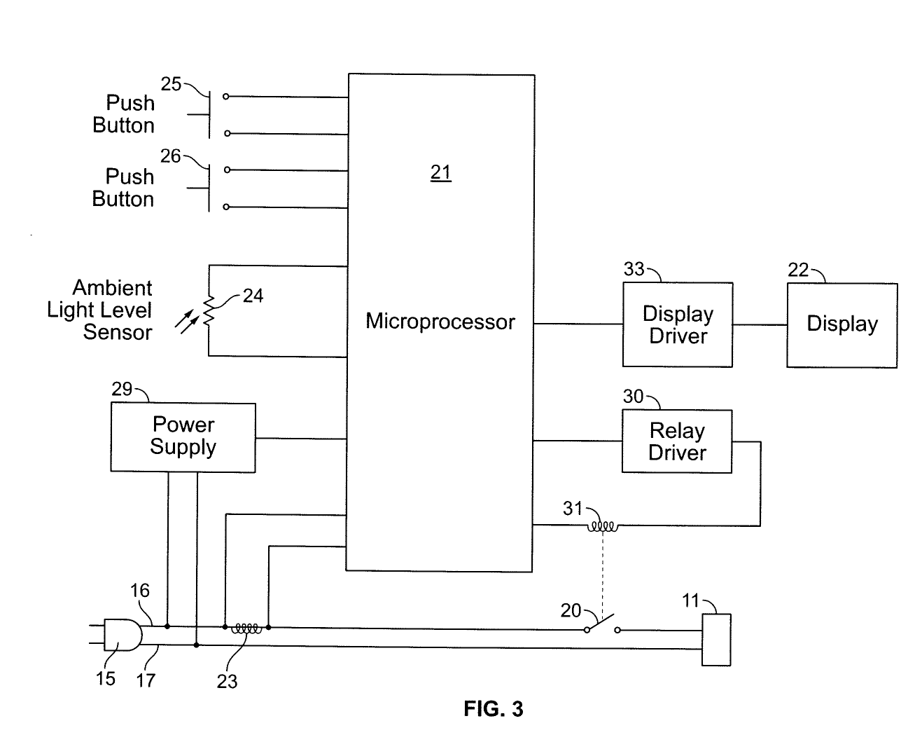

Turning now to the drawings and referring first to FIG. 1, a digital outdoor timer includes a housing 10 that includes a socket 11 for receiving a plug 12 on the end of a power-cord 13 of an electrical appliance, such as a string of decorative lights. An electrical power cord 14 extends from the end of the housing 10 and terminates in a plug 15 that can be plugged into a standard electrical power outlet 16.

Within the housing 10, the cord 14 is electrically connected to the socket 11 through a relay-operated switch 20. A microprocessor 21 receives input signals from multiple sensors and switches and uses these input signals, along with information that it stores, to produce output signals that control both the switch 20 and a display 22. Specifically, the microprocessor 21 receives input signals from (1) a current sensor 23 that detects the magnitude of electrical current flowing through the switch 20 when the switch is closed, and (2) an ambient light sensor 24, such as a conventional cadmium sulfide sensor whose resistance varies in proportion to the intensity of the ambient light, thereby varying the current flow through, and thus the voltage drop across, the sensor 24. The ambient light sensor 24 continuously measures the ambient light level, and the setting of a potentiometer sets an ambient-light threshold. When the ambient light is above the threshold, the switch 20 is maintained in its open position. When the ambient light drops below the threshold, the switch 20 is closed to supply power to the socket 11 and thus to the appliance plugged into that socket.

The microprocessor 21 also receives control signals from a pair of switches 25 and 26 controlled by a pair of pushbuttons 27 and 28 mounted on the front of the housing 10 (see FIG. 1). Pushing the pushbutton 27 momentarily closes the switch 25 to permit the user to set the number of hours that the switch 20 remains closed after being closed in response to the signal from the ambient light sensor 23. Pushing the second pushbutton 28 momentarily closes the switch 26 to reset the display 22, as will be discussed in more detail below.

Power for the microprocessor 21 is supplied from a power supply 29 connected across the plug 15. When a power outage occurs in the power distribution circuit to which the plug 15 is connected, the microprocessor 21 detects the power interruption and uses a backup power supply (e.g., a battery or storage capacitor) to store and display the peak value of the sensed current prior to the interruption.

The microprocessor 21 produces output control signals for a relay driver 30 that controls the energization and de-energization of a relay coil 31 that controls the opening and closing of corresponding relay contacts that form the switch 20. Specifically, closing the relay contacts supplies power to the socket 11, and opening the contacts interrupts power to the socket. Output control signals for a display driver 33 are also produced by the microprocessor 21, to display the number of hours selected by the pushbutton 27 or a numerical value representing the magnitude of electrical current flowing through the meter/timer.

Momentary closing of the switch 25 causes the microprocessor 21 to display the number of hours the power switch 20 is to remain closed before it is automatically opened by a control signal sent from the microprocessor 21 to the relay driver 30. Each time the switch 25 is closed by pushing the pushbutton 27, the selected number of hours is incremented by one, and the display changes to show the new number. The microprocessor can be programmed to reset the selected number of hours to one each time a preselected maximum is reached, e.g., an 8-hour maximum, a 24-hour maximum, etc. The count can also be reset manually via the pushbutton 27. The microprocessor 21 can also be programmed to control both the opening and closing of the power switch 20 in response to the output of the ambient light sensor, as described above.

The second pushbutton-operated switch 26 is used to cause the microprocessor 21 to switch to the meter mode and to select the parameter to be displayed in that mode. The microprocessor 21 is programmed to display a 3-digit number representing the magnitude (in amperes) of the electrical current detected by the current sensor 24. If desired, the microprocessor can also receive a voltage signal from a voltage sensor and compute the power (in watts) being consumed by the load connected to the socket 11. The voltage itself can also be displayed. The microprocessor can be programmed to display these different parameters sequentially in response to successive momentary closings of the switch 26.

The microprocessor continually updates the displayed value representing the magnitude of electrical current flowing through the socket 11 by converting the analog signal from the current sensor 24 into corresponding digital values at repetitive time intervals. The conversion is preferably carried out by an analog-to-digital converter that is on-board the same integrated circuit that forms the microprocessor 21. Each digital value is compared with the previous value, and the maximum value is stored in memory so that the memory always contains the peak value of the electrical current sensed by the meter.

The microprocessor 21 also detects when current is not being supplied by the power circuit supplying power to the meter/timer, which is typically caused by a power failure or the opening of a circuit breaker in the power circuit. When such an event is detected, the peak current value stored in the memory is sustained either by the use of non-volatile memory or by the use of a back-up power supply such as a back-up battery or a storage capacitor. Then when the supply of power to the meter/timer is ultimately restored, the microprocessor 21 retrieves the stored peak current value and displays that value, so that the user can see whether an overload occurred in the circuit that includes the meter/timer.

While particular embodiments and applications of the present invention have been illustrated and described, it is to be understood that the invention is not limited to the precise construction and compositions disclosed herein and that various modifications, changes, and variations may be apparent from the foregoing descriptions without departing from the spirit and scope of the invention as defined in the appended claims.

1. An integrated meter/timer comprising
a plug adapted to be plugged into an electrical outlet connected to a power distribution circuit,
a socket for receiving a plug from an electrical appliance,
an electrical connection between said plug and said socket that includes an automatically operable switch for opening and closing said electrical connection to control the supplying of electrical power to said appliance,
a current sensor coupled to said electrical connection for producing a signal representing the magnitude of electrical current flowing in said electrical connection,
a microprocessor receiving said signal and producing a display signal representing a numerical value corresponding to said current magnitude, and
a display coupled to said microprocessor for receiving said display signal for displaying said numerical value,
said microprocessor also producing a signal controlling the opening and closing said switch to turn said appliance on and off.

2. The integrated meter/timer of claim 1 which includes a memory and said microprocessor is programmed to store the peak value of said current magnitude in said memory, and to retrieves said stored peak value for display.

3. The integrated meter/timer of claim 2 in which said power circuit includes a circuit breaker, and said memory includes non-volatile memory for storing said peak value.

4. The integrated meter/timer of claim 2 in which said power circuit includes a circuit breaker, and which includes a back-up power supply for maintaining said stored peak value during a power outage.

5. The integrated meter/timer of claim 2 which includes a manually operated pushbutton for generating a display control signal, and said microprocessor is programmed to retrieve said stored peak value for display in response to said display control signal.

6. The integrated meter/timer of claim 1 which includes a manually operated switch coupled to said microprocessor for resetting said display after said peak value has been displayed.

7. The integrated meter/timer of claim 1 which includes an ambient light sensor for generating a switch control signal, and said microprocessor is programmed to generate a switch actuating signal in response to said switch control signal.

8. The integrated meter/timer of claim 7 in which said microcontroller produces a control signal in response to the output of said ambient light sensor, and which includes a relay for opening and closing said switch, and a relay driver for actuating said switch in response to said control signal.
